(19) United States
(12) Patent Application Publication
(10) Pub. No.: US 2025/0366106 A1
(43) Pub. Date: Nov. 27, 2025

(54) Structure of a Planar MOS-gated Semiconductor Device

(71) Applicant: NATIONAL TSING HUA UNIVERSITY, Hsinchu City (TW)

(72) Inventors: CHIH-FANG HUANG, Hsinchu City (TW); JIA-WEI HU, Taipei City (TW)

(21) Appl. No.: 18/670,145

(22) Filed: May 21, 2024

(30) Foreign Application Priority Data
May 23, 2023 (TW) 112119197

(51) Int. Cl. H01L 29/06; H01L 27/088; H01L 29/78

(52) U.S. Cl. CPC H10D 62/127; H10D 30/66; H10D 62/106; H10D 84/83

(57) ABSTRACT

A structure of a planar metal-oxide-semiconductor-gated (MOS-gated) semiconductor device has an active region and a non-active region. The active region includes: multiple hexagonal active region units, which are arranged closely adjacent to each other to cover the active region, and form a plane of the active region. The hexagonal active region units surround the non-active region, and the non-active region unit is connected to at least one of the hexagonal active region units. The active region includes a channel formed by MOS structure in inversion or accumulation, while the non-active region does not include a channel.

### CROSS-REFERENCE TO RELATED APPLICATIONS

This application claims priority of No. 112119197 filed in Taiwan R.O.C. on May 23, 2023, the entire content of which is hereby incorporated by reference.

### FIELD OF THE INVENTION

This disclosure relates to a structure of a metal oxide semiconductor field effect transistor (MOSFET), and more particularly to a structure of a planar gate MOSFET having an active region or a non-active region, which has hexagonal units arranged closely adjacent to each other.

### DESCRIPTION OF RELATED ART

Conventional silicon carbide power devices have the advantages of withstanding a higher voltage and having a lower resistance than their silicon counterparts. However, a planar gate silicon carbide MOSFET typically has a very low channel mobility due to the poor MOS interface properties, resulting in a high channel resistance. Therefore, the on-resistance of planar gate silicon carbide MOSFETs is usually much higher than its theoretical value

### SUMMARY OF THE INVENTION

This disclosure discloses an improved planar gate MOSFET capable of effectively increasing the channel density, or channel width per unit area (W/Area), in the active region, and thus decreasing the channel resistance and the component's on-resistance, or alternatively decreasing the chip size of a planar gate MOSFET, so that the conventional problem of the higher on-resistance can be improved.

This disclosure discloses a structure of a planar gate MOSFET having an active region and a non-active region. The active region includes: multiple hexagonal active region units, which are arranged closely adjacent to each other to cover the active region and form a plane of the active region. The hexagonal active region units surround the non-active region, and the non-active region is connected to at least one of the hexagonal active region units. The active region unit includes a channel formed by MOS structure in inversion or accumulation, and the non-active region does not include a channel.

According to an embodiment of this disclosure, the non-active region has one or multiple hexagonal non-active region units, the hexagonal active region units surround the non-active region, and the hexagonal non-active region unit is connected to at least one of the hexagonal active region units.

According to an embodiment of this disclosure, the non-active region has multiple hexagonal non-active region units arranged closely adjacent to each other, wherein the structure of the planar gate MOSFET has no independent one of the hexagonal non-active region units being surrounded by the multiple hexagonal non-active region units.

### BRIEF DESCRIPTION OF DRAWINGS

FIG. 1 is a simplified schematic top view showing a structure 100 of a planar gate MOSFET according to an embodiment of this disclosure.

FIG. 2 is a simplified schematic top view showing a structure 200 of a planar gate MOSFET according to an embodiment of this disclosure.

FIG. 3 is a simplified schematic top view showing a structure 300 of a planar gate MOSFET according to an embodiment of this disclosure.

FIG. 4A is a simplified schematic top view showing a structure 400 of a planar gate MOSFET according to an embodiment of this disclosure.

FIG. 4B is a planar schematic view showing each region in the structure 400 of FIG. 4A.

FIG. 5 is a planar schematic view showing each region in a structure 500 of another embodiment.

FIG. 6 is a schematic view showing a cross section AA in FIG. 4B or 5.

FIG. 7A is a schematic view showing a cross section BB in FIG. 4B.

FIG. 7A_1 is a schematic view showing the cross section BB in FIG. 4B in an embodiment.

FIG. 7A_2 is a planar schematic view showing each region of a structure 400A.

FIG. 7A_3 is a schematic view showing the cross section BB in FIG. 7A_2 in an embodiment.

FIG. 7A_4 is a planar schematic view showing each region of a structure 400B.

FIG. 7A_5 is a schematic view showing the cross section BB in FIG. 7A_4 in an embodiment.

FIG. 7B is a schematic view showing the cross section BB in FIG. 4 in another embodiment.

FIG. 8A is a schematic view showing a cross section B′B′ in FIG. 5 in an embodiment.

FIG. 8B is a schematic view showing the cross section B′B′ in FIG. 5 in another embodiment.

) FIG. 9 is a planar schematic view showing a structure 900 in an embodiment.

FIG. 10 is a schematic view showing a cross section CC in the structure 900 in an embodiment.

### DETAILED DESCRIPTION OF THE INVENTION

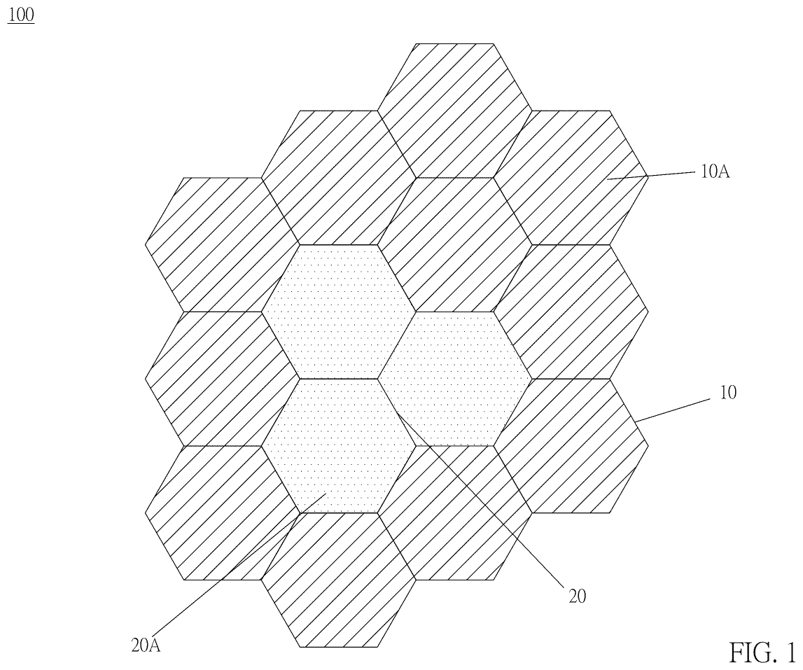

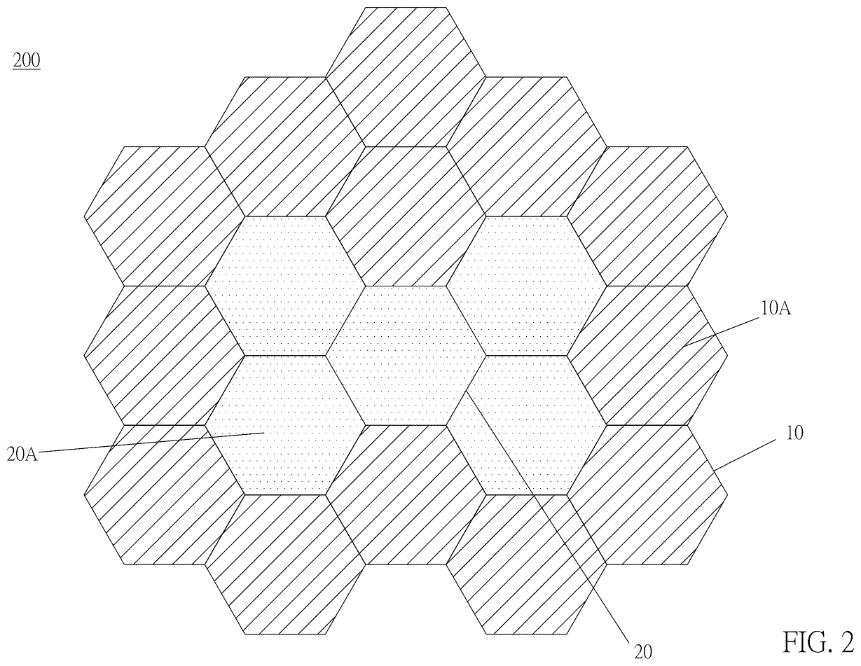

Please refer to FIG. 1. FIG. 1 is a simplified schematic top view showing a structure 100 of a planar gate MOSFET according to an embodiment of this disclosure. The structure 100 has a gate pad region (not shown), an edge terminal region (not shown), an active region 10 (hatched region), and a non-active region 20 (dotted region). The active region 10 includes multiple hexagonal active region units 10A, which are hexagonal regions, and arranged closely adjacent to each other to cover the active region 10 to form a plane of the active region 10. Correspondingly, the non-active region 20 may have at least one hexagonal non-active region unit 20A. The active region 10 surrounds the non-active region 20. That is, the hexagonal active region units 10A surround the non-active region 20 or the hexagonal non-active region unit 20A. Please note that the hexagonal non-active region unit 20A is connected to at least one of the hexagonal active region units 10A, or the hexagonal non-active region unit 20A is connected to at least a neighboring one of the hexagonal active region units 10A.

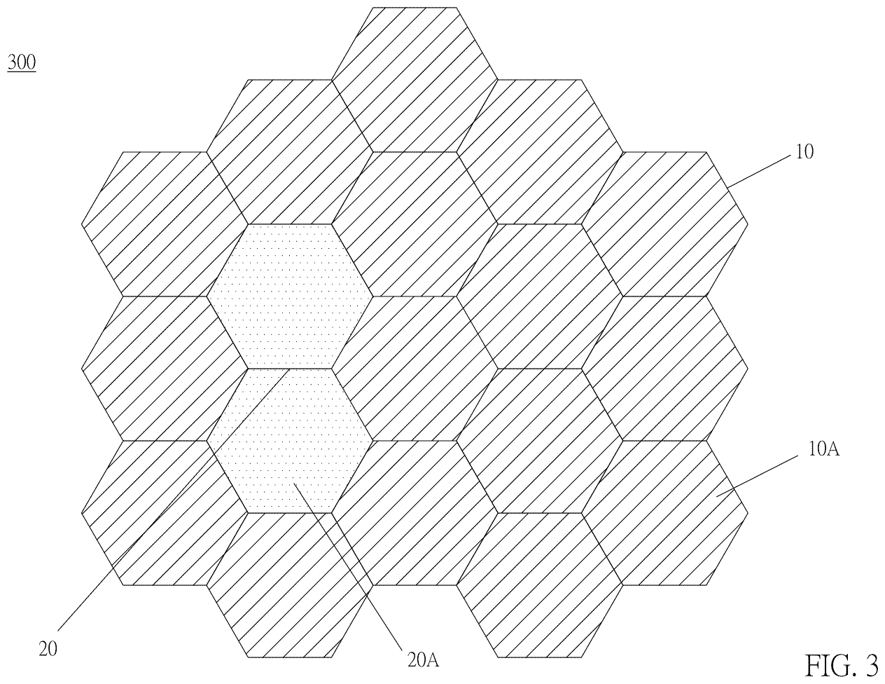

Please refer to FIGS. 2 and 3. FIGS. 2 and 3 are simplified schematic top views respectively showing structures 200 and 300 of planar gate MOSFETs according to embodiments of this disclosure. As previously mentioned, this embodiment has multiple hexagonal non-active region units 20A, but this disclosure should not be restricted thereto, and the hexagonal non-active region units 20A are arranged closely adjacent to each other. It is to be noted that there is no isolated hexagonal non-active region unit 20A being surrounded by the multiple hexagonal non-active region units 20A in this disclosure.

Please note that the layout of the active region 10 and the non-active region 20 in the structure of the planar gate MOSFET can effectively decrease the dimensions of the planar gate MOSFET because the hexagonal active region units 10A or the hexagonal non-active region units 20A are arranged closely adjacent to each other. Thus, a higher unit density in the active region 10 or the non-active region 20 can be obtained. That is, the channel density, or channel width per unit area (W/Area), in the active region 10 can be increased, and the channel's on-resistance and total resistance can be decreased.

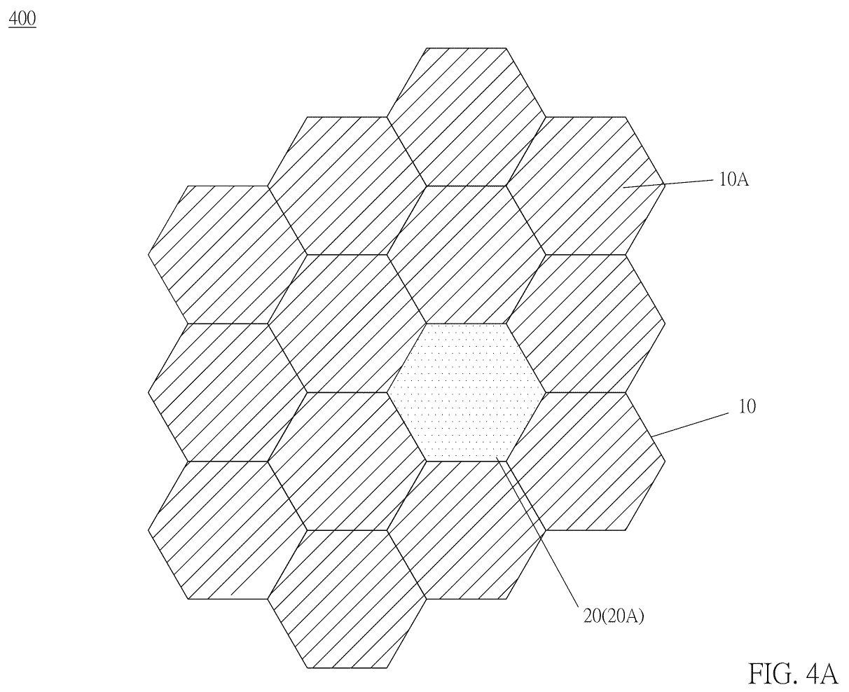

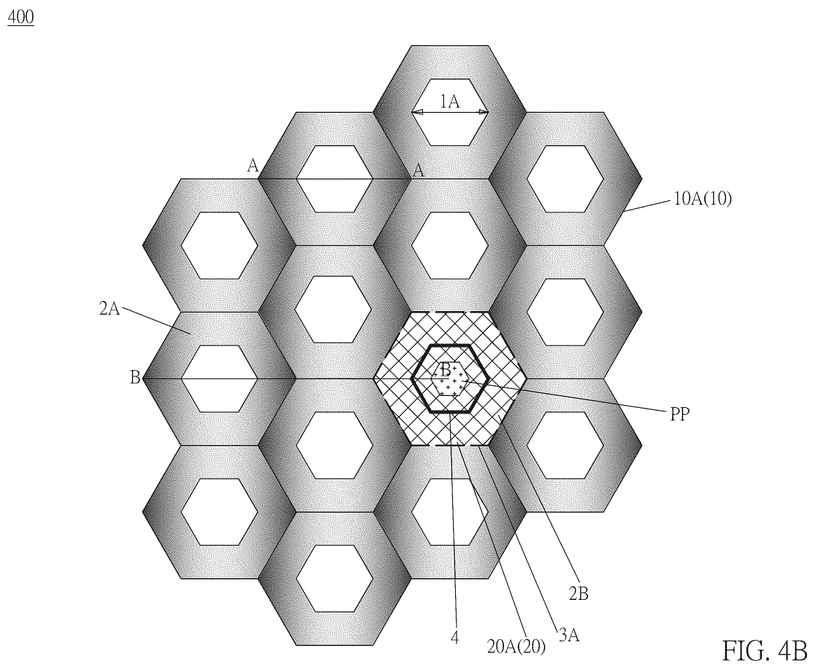

Please refer to FIGS. 4A and 4B. FIG. 4A is a simplified schematic top view showing a structure 400 of a planar gate MOSFET according to an embodiment of this disclosure. FIG. 4B is a planar schematic view showing each region in the structure 400 of FIG. 4A.

The hexagonal active region unit 10A of the structure 100 includes a first junction field effect transistor (junction gate field-effect transistor, hereinafter referred to as JFET) region 1A and a first P-type well 2A (grayscale gradient region). The first JFET region 1A is a hexagonal region. The first P-type well 2A starts from the edge of the hexagonal active region unit 10A to surround the first JFET region 1A. The first JFET region 1A is disposed in the first P-type well 2A, or the first JFET region 1A may be regarded as being disposed between the adjacent first P-type wells 2A. The first P-type well 2A includes a first N⁺-type semiconductor region N⁺_1 (not shown).

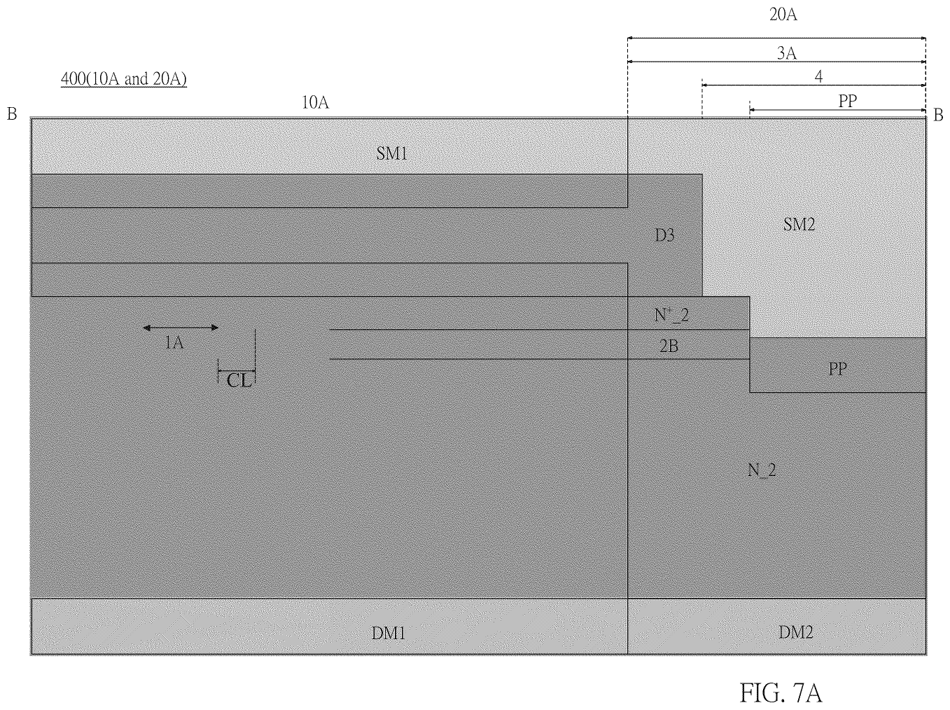

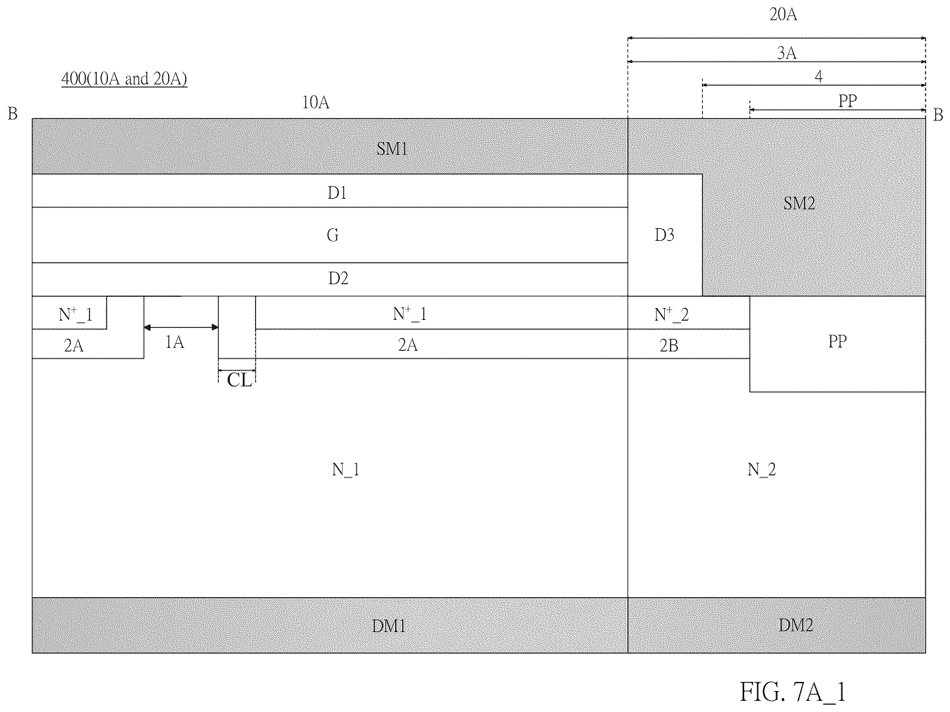

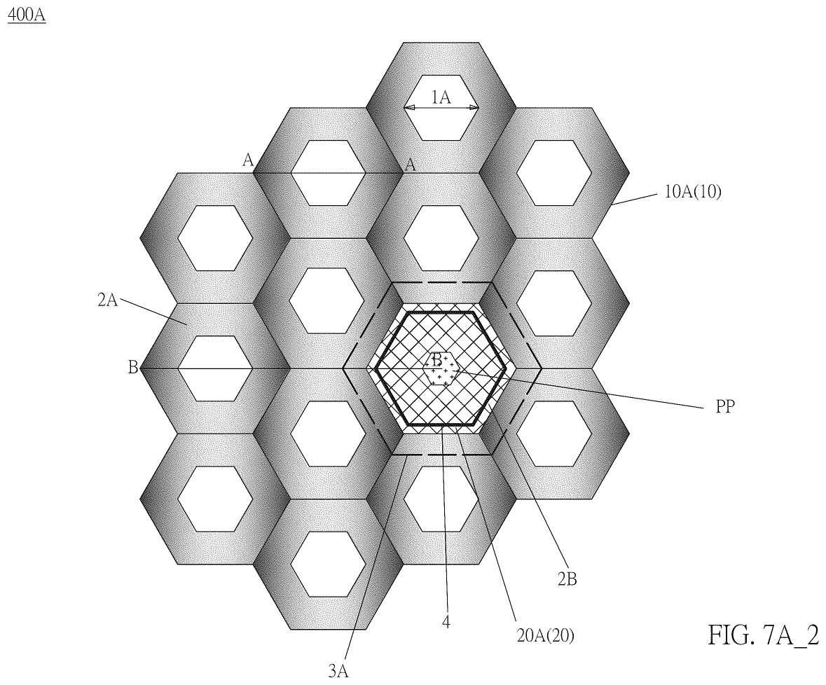

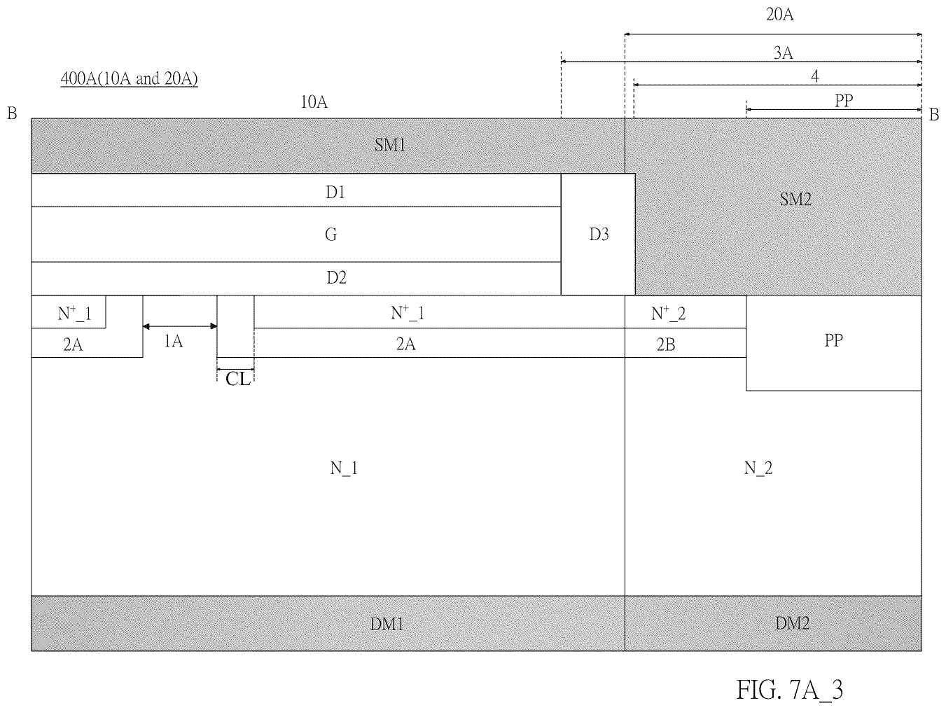

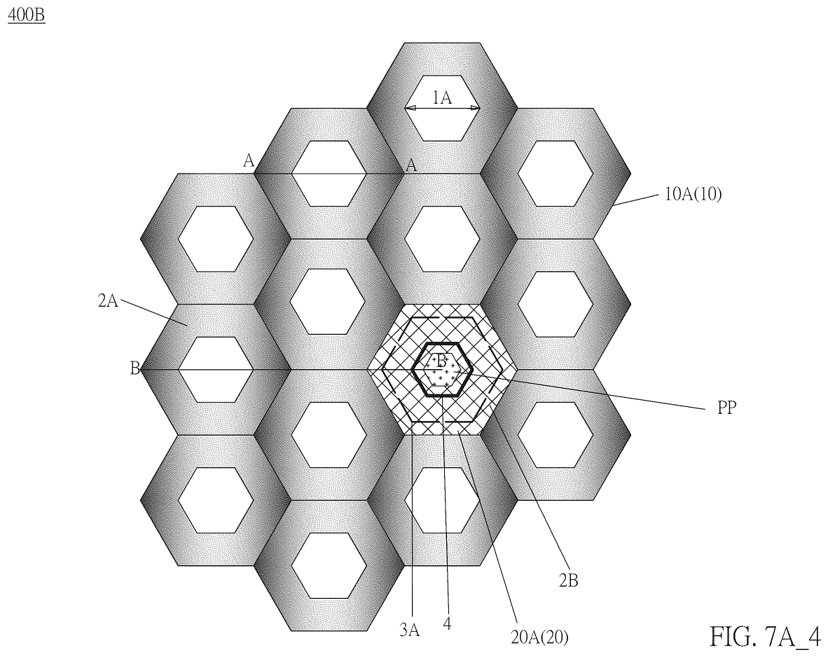

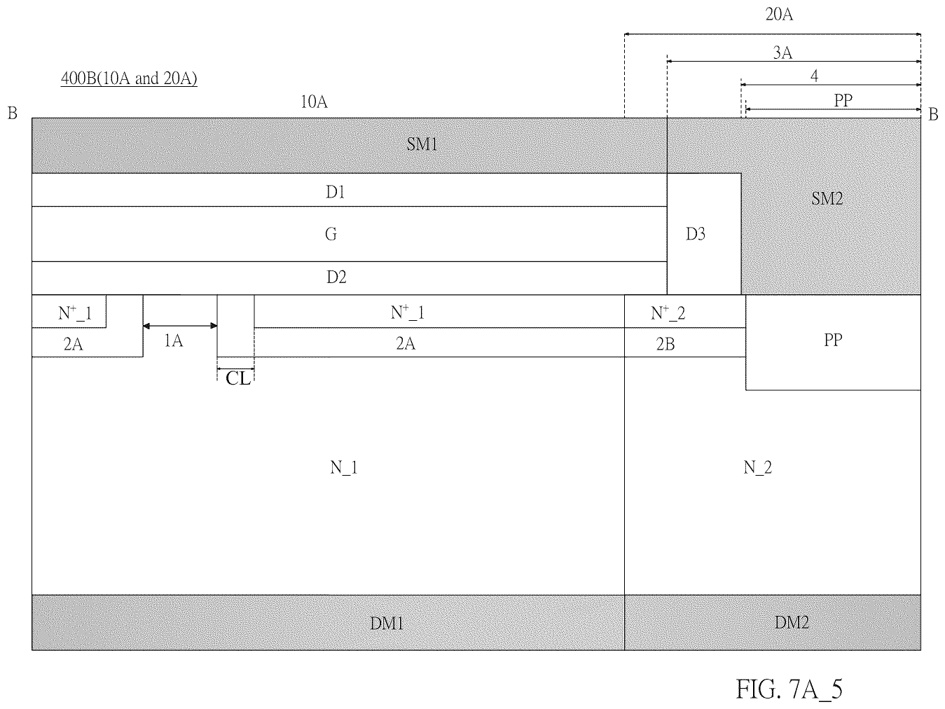

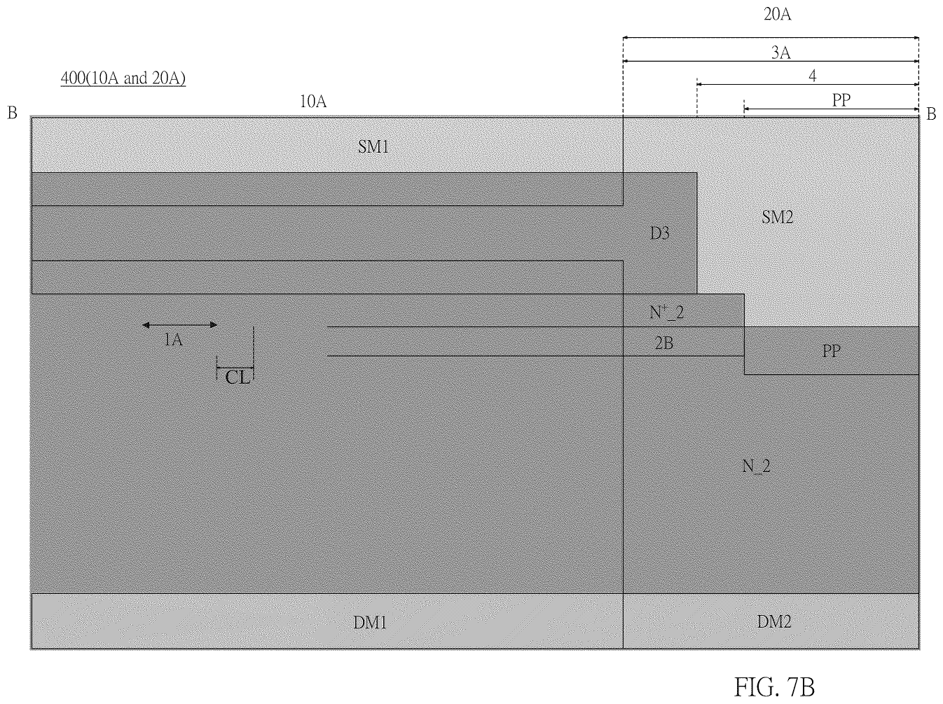

In addition, the hexagonal non-active region unit 20A includes: a first polycrystalline gate opening region 3A, a second P-type well 2B, a metal-semiconductor contact region 4 and a high concentration P-type region PP. The second P-type well 2B and the metal-semiconductor contact region 4 are hexagonal regions. The first polycrystalline gate opening region 3A may start from the edge of the hexagonal non-active region unit 20A, or may be wider or narrower than the edge (see FIGS. 4B, 7A_2, and 7A_4), wherein portions in the hexagonal non-active region unit 20A pertain to the first polycrystalline gate opening region 3A. The second P-type well 2B is disposed in the first polycrystalline gate opening region 3A, the second P-type well 2B surrounds the metal-semiconductor contact region 4, and the high concentration P-type region PP contacts the metal-semiconductor contact region 4. A region of a combination of the second P-type well 2B and the high concentration P-type region PP covers the entire planar range of the non-active region 20. The metal-semiconductor contact region 4 has six lateral sides adjacent to the active regions 10.

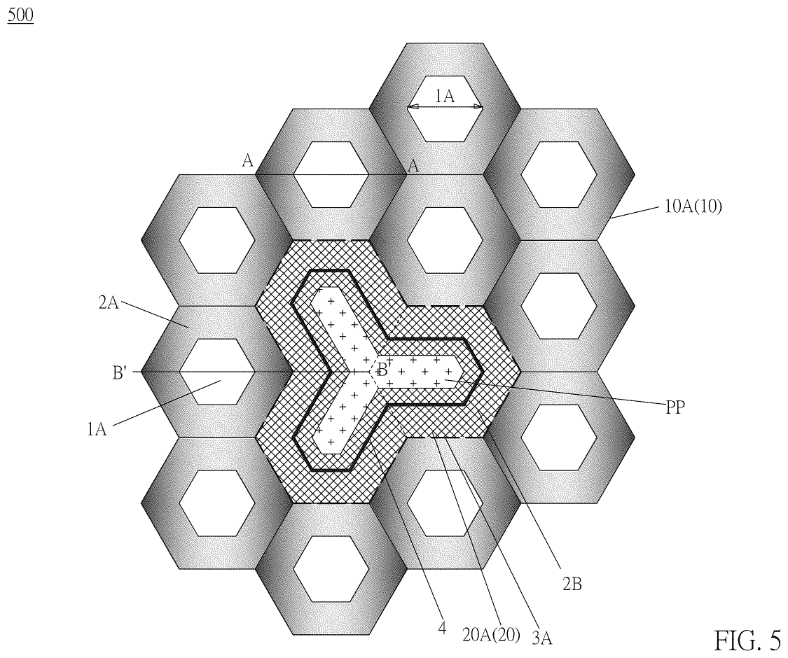

Please refer to FIG. 5. FIG. 5 is a planar schematic view showing each region in a structure 500 of another embodiment. Please note that the difference between the structure 500 and the structure 100 resides in that the structure 500 has three hexagonal non-active region units 20A arranged and connected closely to each other. The high concentration P-type regions PP of the three hexagonal non-active region unit 20A are arranged and connected closely to each other, and the metal-semiconductor contact regions 4 of the three hexagonal non-active region units 20A are arranged and connected closely to each other. The metal-semiconductor contact region 4 has twelve lateral sides adjacent to the active regions 10.

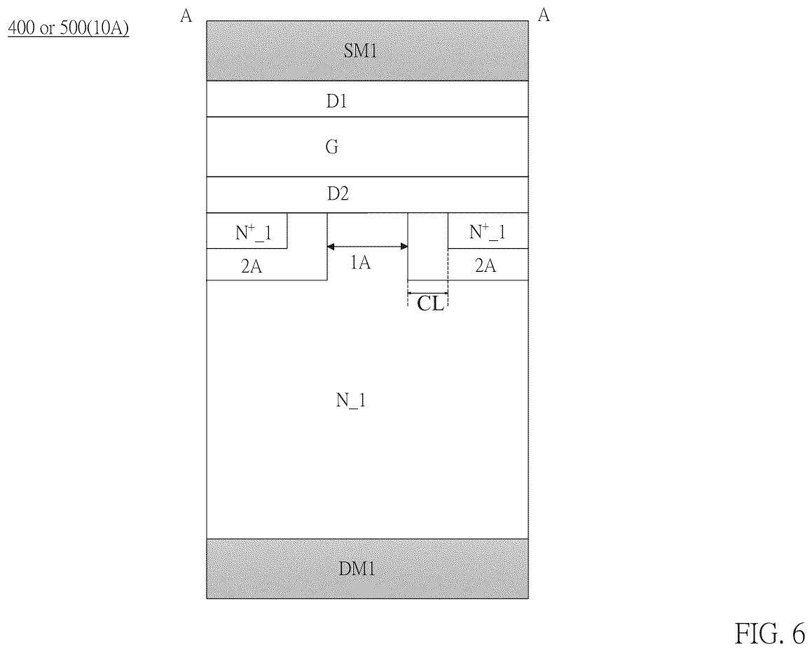

Please refer to FIG. 6. FIG. 6 is a schematic view showing a cross section AA in FIG. 4B or 5. In this embodiment, the cross section AA is a cross section of one hexagonal active region unit 10A. In the cross section AA, the structure 400 or 500 includes: a first source metal SM1, a first dielectric region D1, a gate G, a second dielectric region D2, a first N⁺-type semiconductor region N⁺_1, a first P-type well 2A, a first N-type semiconductor region N_1, and a first drain metal DM1. The material of the gate may be polysilicon, metal silicide, metal, or a combination thereof.

The first dielectric region D1 has an upper surface covered by the first source metal SM1. The gate G has an upper surface covered by the first dielectric region D1. The second dielectric region D2 has an upper surface covered by a bottom surface of the gate G. The first N⁺-type semiconductor region N⁺_1 has an upper surface contacting a bottom surface of the second dielectric region D2, and a bottom surface contacting the first P-type well 2A. The first P-type well 2A covers the first N⁺-type semiconductor region N⁺_1. The first N-type semiconductor region N_1 covers a sidewall and a bottom surface of the first P-type well 2A. The first drain metal DM1 is covered by a bottom surface of the first N-type semiconductor region N_1. A distance from an edge of the first P-type well 2A to an edge of the first N⁺-type semiconductor region N⁺_1 covered by the first P-type well 2A is a channel length (CL), and the JFET region 1A may be regarded as being disposed between the adjacent first P-type wells 2A. A doping concentration of the first N-type semiconductor region N_1 may be a uniform concentration or a non-uniform concentration. That is, in one embodiment, a current spreading layer (CSL) (not shown) is present in the first P-type well 2A and the first N-type semiconductor region N_1.

Please refer to FIG. 7A. FIG. 7A is a schematic view showing a cross section BB in FIG. 4B. The cross section BB of the structure 400 covers the hexagonal active region unit 10A and the hexagonal non-active region unit 20A. The hexagonal non-active region unit 20A includes a second source metal SM2, a third dielectric region D3, a second N⁺-type semiconductor region N⁺_2, a second P-type well 2B, a high concentration P-type region PP, a second N-type semiconductor layer region N_2 and a second drain metal DM2. A material of the high concentration P-type region PP is the heavily doped P-type silicon, silicon carbide, gallium nitride or gallium oxide. Please note that the ending point of the line segment depicted in the cross section BB of the FIG. 4B is at the high concentration P-type region PP, but the high concentration P-type region PP is not restricted to be the center of the hexagonal non-active region unit 20A.

The third dielectric region D3 has an upper surface and one of the sidewalls covered by the second source metal SM2. An ending edge of the third dielectric region D3 is a starting edge of the metal-semiconductor contact region 4. One portion of an upper surface of the second N⁺-type semiconductor region N⁺_2 contacts a bottom surface of the third dielectric region D3, the other portion of the upper surface contacts a bottom surface of the second source metal, and a sidewall of the second N⁺-type semiconductor region N⁺_2 contacts the second source metal SM2. The second N⁺-type semiconductor region N⁺_2 has a bottom surface covering an upper surface of the second P-type well 2B. A depth of a bottom surface of the high concentration P-type region PP is greater than the second P-type well 2B, and a portion of a sidewall of the high concentration P-type region PP contacts one sidewall of the second P-type well 2B. The second N-type semiconductor region N_2 covers a bottom surface of the second P-type well 2B and the other portion of the sidewall and a bottom surface of the high concentration P-type region PP. The second drain metal DM2 covers a bottom surface of the second N-type semiconductor region N_2. A range of the second source metal SM2 is the first polycrystalline gate opening region 3A, and a range of the second source metal SM2 exclusive of the third dielectric region D3 is the metal-semiconductor contact region 4. In this embodiment, the first polycrystalline gate opening region 3A may start from the edge of the hexagonal non-active region unit 20A.

Please note that a depth of an interface of the second source metal SM2 and the high concentration P-type region PP may range from the depth of the upper surface of the second N⁺-type semiconductor region N⁺_2 to the depth of the second P-type well 2B. In FIG. 7A_1, the depth of the interface of the second source metal SM2 and the high concentration P-type region PP is equal to the depth of the upper surface of the second N⁺-type semiconductor region N⁺_2. The second source metal SM2 has a bottom surface covering an upper surface of the high concentration P-type region PP. The second source metal SM2 has a bottom surface covering a portion of the upper surface of the second N⁺-type semiconductor region N⁺_2.

Please note that the first polycrystalline gate opening region 3A may be wider than the edge of the hexagonal non-active region unit 20A, as shown in FIGS. 7A_2 and 7A_3, wherein the bottom surface of the third dielectric region D3 contacts a portion of the upper surface of the first N⁺-type semiconductor region N⁺_1 and a portion of the upper surface of the second N⁺-type semiconductor region N⁺_2; and the first polycrystalline gate opening region 3A may be narrower than the edge of the hexagonal non-active region unit 20A, as shown in FIGS. 7A_4 and 7A_5, wherein the bottom surface of the third dielectric region D3 contacts a portion of the upper surface of the second N⁺-type semiconductor region N⁺_2. Please note that the ending point of the line segment depicted in the cross section BB of FIG. 7A_2 is at the high concentration P-type region PP, but the high concentration P-type region PP is not restricted to be the center of the hexagonal non-active region unit 20A.

Please refer to FIG. 7B. FIG. 7B is a schematic view showing the cross section BB in FIG. 4 in another embodiment. The difference between FIGS. 7A and 7B resides in that the depth of the interface of the second source metal SM2 and the high concentration P-type region PP is equal to the depth of the interface of the second N⁺-type semiconductor region N⁺_2 and the second P-type well 2B. The sidewall of the second source metal SM2 covers a portion of the upper surface and one of the sidewalls of the second N⁺-type semiconductor region N⁺_2, wherein the other structures are the same as those mentioned hereinabove, and detailed descriptions thereof will be omitted.

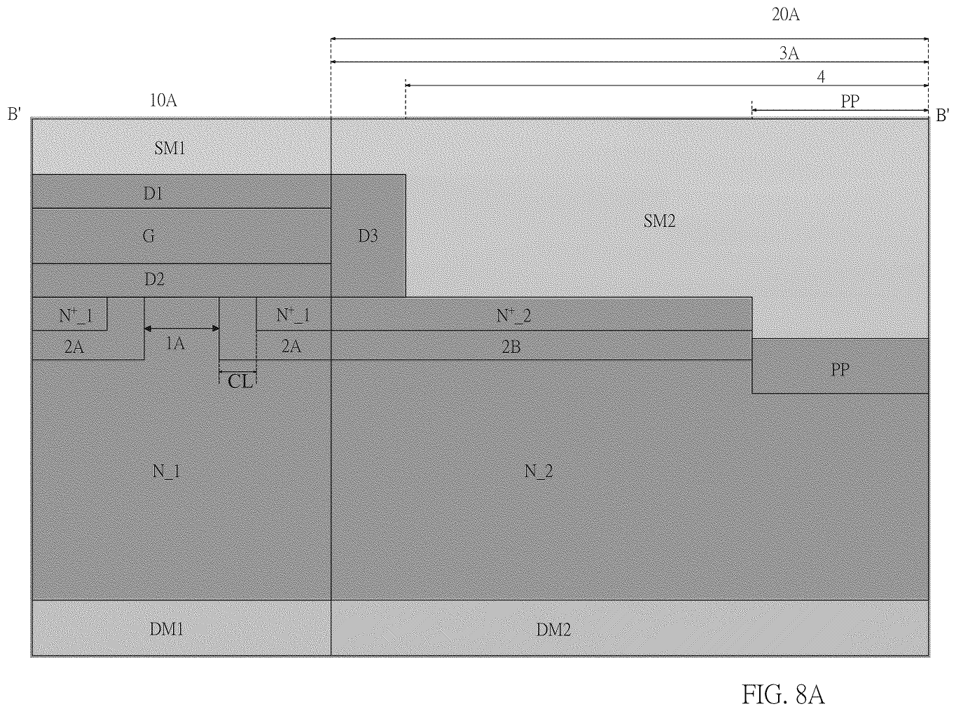

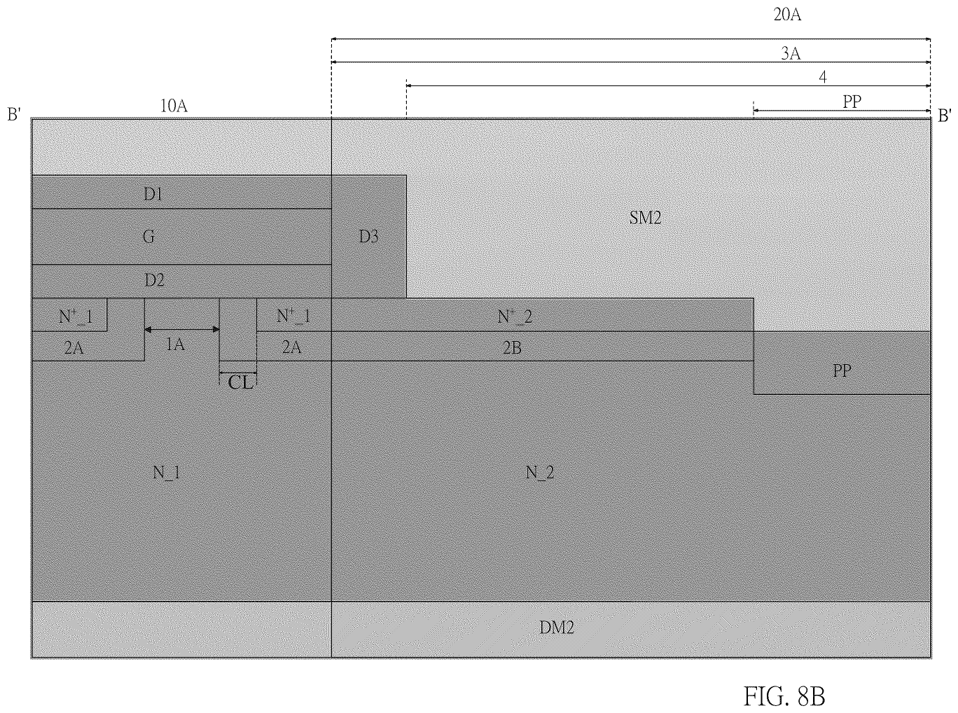

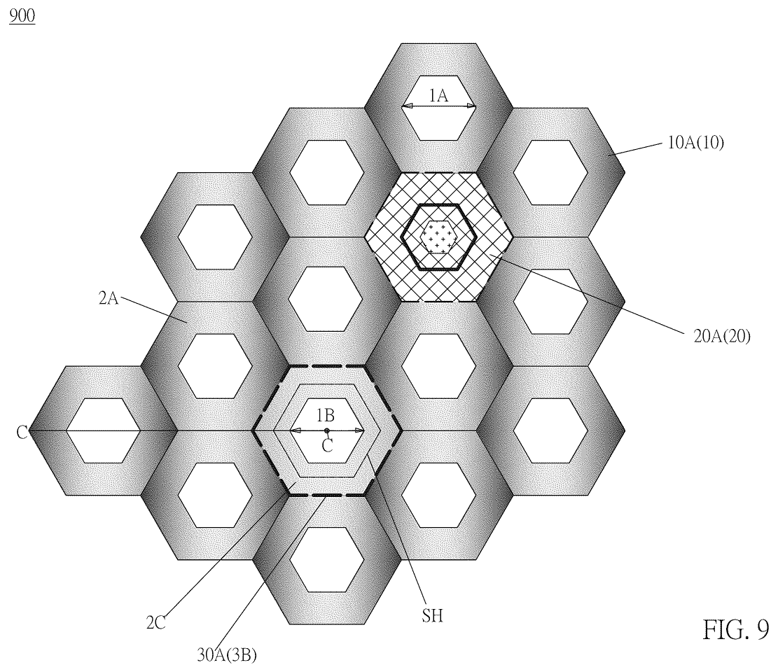

Please refer to FIG. 8A. FIG. 8A is a schematic view showing a cross section B′B′ in FIG. 5 in an embodiment. The cross section B′B′ of the structure 500 covers the hexagonal active region unit 10A and the hexagonal non-active region unit 20A. The difference between the hexagonal non-active region unit 20A in the cross section B′B′ of FIG. 8A and the hexagonal non-active region unit 20A in the cross section BB of FIG. 7A resides in that the ranges of the polycrystalline gate opening region 3A, the metal-semiconductor contact region 4 and the high concentration P-type region PP in the cross section B′B′ are respectively larger than those in the cross section BB.

Similarly, please refer to FIG. 8B. FIG. 8B is a schematic view showing the cross section B′B′ in FIG. 5 in another embodiment. The difference between the hexagonal non-active region unit 20A in the cross section B′B′ of FIG. 8B and the hexagonal non-active region unit 20A in the cross section BB of FIG. 7B resides in that the ranges of the polycrystalline gate opening region 3A, the metal-semiconductor contact region 4, and the high concentration P-type region PP in the cross section B′B′ are respectively larger than those in the cross section BB.

Please note that the layout of the active region of this disclosure using hexagonal units has the highest channel density, and can effectively decrease the on-resistance Rdson of the MOSFET. In addition, the active region and the non-active region are configured using the hexagonal units, so that these units are arranged in the most compact manner to increase the density. In addition, this disclosure has three characteristics.

First, no metal-semiconductor contact region is present in the hexagonal active region unit, so the active region can be effectively utilized and the overall area of the component can be reduced.

Second, the metal-semiconductor contact region may be formed by one hexagonal unit or multiple hexagonal units connected together to increase the area of the metal-semiconductor contact region and decrease the contact resistance of the structure.

Third, the distances from the position of the metal-semiconductor contact region to the positions of the nearest channels are fixed, so it is possible to prevent the parasitic BJT effect from occurring early and to improve the durability of the structure.

Please refer to FIG. 9. FIG. 9 is a planar schematic view showing a structure 900 in an embodiment. In this embodiment, the structure 900 has the hexagonal active region unit 10A and the hexagonal non-active region unit 20A, and further has one or multiple closely connected hexagonal non-active region units 30A. The other characteristics are the same as those mentioned hereinabove, and detailed descriptions thereof will be omitted.

The hexagonal non-active region unit 30A includes a second polycrystalline gate opening region 3B, a third P-type well 2C, a second JFET region 1B, and a Schottky contact region SH. The Schottky contact region SH and the second JFET region 1B are hexagonal regions, and the second polycrystalline gate opening region 3B starts from the edge of the hexagonal non-active region unit 30A. Portions in the hexagonal non-active region unit 30A pertain to the second polycrystalline gate opening region 3B. The third P-type well 2C is disposed in the second polycrystalline gate opening region 3B, and the third P-type well 2C is disposed between the second JFET region 1B and the second polycrystalline gate opening region 3B. The third P-type well 2C surrounds the second JFET region 1B. The Schottky contact region SH is disposed in the second polycrystalline gate opening region 3B, and the Schottky contact region SH is disposed between the second JFET region 1B and the second polycrystalline gate opening region 3B. The range of the Schottky contact region SH is smaller than the third P-type well 2C. Please note that the ending point of the line segment depicted in a cross section CC of FIG. 9 is not restricted to be the center of the hexagonal non-active region unit 30A.

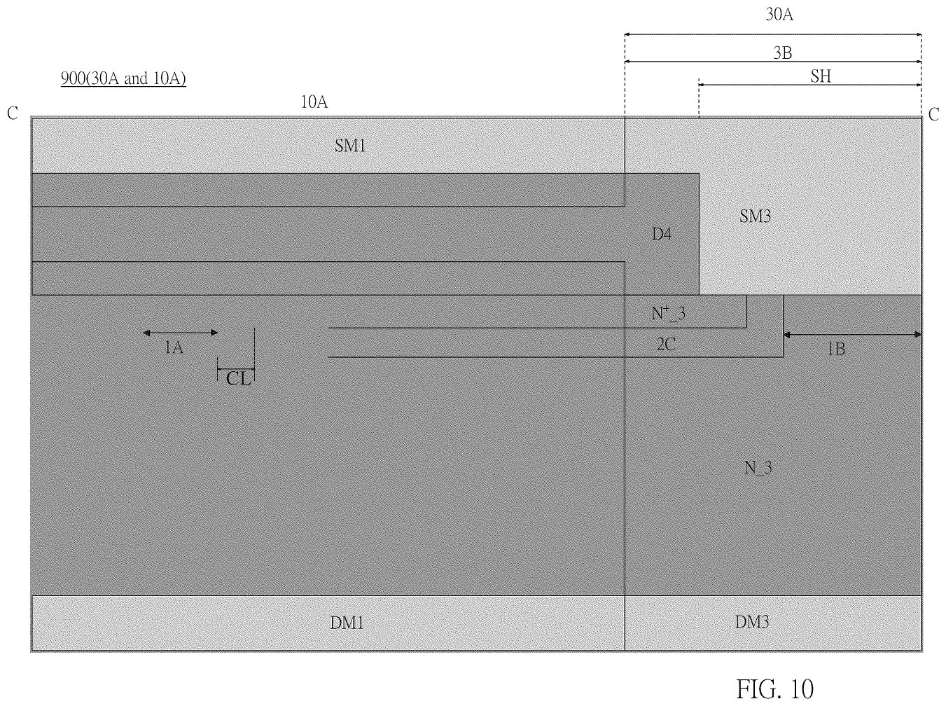

Please refer to FIG. 10. FIG. 10 is a schematic view showing the cross section CC in the structure 900 in an embodiment. The cross section CC of the structure 900 covers the hexagonal active region unit 10A, and the hexagonal non-active region units 20A and 30A. The hexagonal non-active region unit 30A includes: a third source metal SM3, a fourth dielectric region D4, a third N⁺-type semiconductor region N⁺_3, a third N-type semiconductor region N_3, and a third drain metal DM3.

The fourth dielectric region D4 has an upper surface and one sidewall covered by the third source metal SM3, and an ending edge being the starting edge of the Schottky contact region SH. One portion of an upper surface of the third N⁺-type semiconductor region N⁺_3 contacts a bottom surface of the fourth dielectric region D4, the other portion of the upper surface of the third N⁺-type semiconductor region N⁺_3 contacts the bottom surface of the third source metal SM3, and the third P-type well 2C covers the third N⁺-type semiconductor region N⁺_3 and contacts the bottom surface of the third source metal SM3. The third N-type semiconductor region N_3 covers the bottom surface and the sidewall of the third P-type well 2C, and the interface of the third N-type semiconductor region N_3 and the third source metal SM3 is the Schottky junction. The third drain metal DM3 covers the bottom surface of the third N-type semiconductor region N_3. The range of the third source metal DM3 is the second polycrystalline gate opening region 3B, and the range of the second source metal SM2 exclusive of the fourth dielectric region D4 is the Schottky contact region SH.

In summary, the P-type well in the above-mentioned embodiments may be replaced by the N-type well. Correspondingly, the N⁺-type semiconductor region is replaced by the P⁺-type semiconductor region, and the N-type semiconductor region is replaced by the P-type semiconductor region. For the sake of conciseness, detailed descriptions thereof will be omitted. In addition, the planar metal-oxide-semiconductor-gated semiconductor device is implemented by a metal-oxide-semiconductor field-effect transistor (MOSFET) or an insulated gate bipolar transistor (IGBT).

1. A structure of a planar metal-oxide-semiconductor-gated semiconductor device having an active region and a non-active region, wherein the active region comprises:
multiple hexagonal active region units, which are arranged closely adjacent to each other to cover the active region, and form a plane of the active region;
wherein the hexagonal active region units surround the non-active region, and the non-active region is connected to at least one of the hexagonal active region units; and the active region comprises a channel formed by MOS structure in inversion or accumulation, while the non-active region does not comprise a channel.

2. The structure according to claim 1, wherein the non-active region has one or multiple hexagonal non-active region units, the hexagonal active region units surround the non-active region, and the hexagonal non-active region unit is connected to at least one of the one or multiple hexagonal active region units.

3. The structure according to claim 2, wherein the non-active region has the multiple hexagonal non-active region units arranged closely adjacent to each other, but there is no independent one of the hexagonal non-active region units being surrounded by the multiple hexagonal non-active region units.

4. The structure according to claim 1, wherein each of the hexagonal active region units comprises:
a first JFET region; and
a first first-type semiconductor well;
wherein the first JFET region is a hexagonal region, the first first-type semiconductor well starts to surround the first JFET region from edges of the hexagonal active region units, and the first JFET region is disposed in the first first-type semiconductor well or between adjacent two of the first first-type semiconductor wells.

5. The structure according to claim 2, wherein each of the hexagonal active region units comprises:
a first JFET region; and
a first first-type semiconductor well;
wherein the first JFET region is a hexagonal region, the first first-type semiconductor well starts to surround the first JFET region from edges of the hexagonal active region units, and the first JFET region is disposed in the first first-type semiconductor well or between adjacent two of the first first-type semiconductor wells.

6. The structure according to claim 3, wherein each of the hexagonal active region units comprises:
a first JFET region; and
a first first-type semiconductor well;
wherein the first JFET region is a hexagonal region, the first first-type semiconductor well starts to surround the first JFET region from edges of the hexagonal active region units, and the first JFET region is disposed in the first first-type semiconductor well or between adjacent two of the first first-type semiconductor wells.

7. The structure according to claim 3, wherein the hexagonal non-active region unit comprises:
a first polycrystalline gate opening region;
a second first-type semiconductor well;
a metal-semiconductor contact region; and
a high concentration first-type semiconductor region;
wherein the second first-type semiconductor well and the metal-semiconductor contact region are hexagonal regions, the first polycrystalline gate opening region starts from an edge of the hexagonal non-active region unit, and portions in the hexagonal non-active region unit pertain to the first polycrystalline gate opening region; the second first-type semiconductor well is disposed in the first polycrystalline gate opening region, and the second first-type semiconductor well surrounds the metal-semiconductor contact region; and the high concentration first-type semiconductor region contacts the metal-semiconductor contact region;
wherein a region of a combination of the second first-type semiconductor well and the high concentration first-type semiconductor region covers an entire planar range of the non-active region.

8. The structure according to claim 4, wherein a cross section of the hexagonal active region units comprises:
a first source metal;
a first dielectric region having an upper surface covered by the first source metal;
a gate having an upper surface covered by the first dielectric region;
a second dielectric region having an upper surface covered by a bottom surface of the gate;
a first high concentration second-type semiconductor region having an upper surface contacting a bottom surface of the second dielectric region, wherein a bottom surface of the first high concentration second-type semiconductor region contacts the first first-type semiconductor well, and the first first-type semiconductor well covers the first high concentration second-type semiconductor region;
a first second-type semiconductor region covering a sidewall and a bottom surface of the first first-type semiconductor well; and
a first drain metal covered by a bottom surface of the first second-type semiconductor region;
wherein a distance from an edge of the first first-type semiconductor well to an edge of the first high concentration second-type semiconductor region covered by the first first-type semiconductor well is a channel length.

9. The structure according to claim 5, wherein a cross section of the hexagonal active region units comprises:
a first source metal;
a first dielectric region having an upper surface covered by the first source metal;
a gate having an upper surface covered by the first dielectric region;
a second dielectric region having an upper surface covered by a bottom surface of the gate;
a first high concentration second-type semiconductor region having an upper surface contacting a bottom surface of the second dielectric region, wherein a bottom surface of the first high concentration second-type semiconductor region contacts the first first-type semiconductor well, and the first first-type semiconductor well covers the first high concentration second-type semiconductor region;
a first second-type semiconductor region covering a sidewall and a bottom surface of the first first-type semiconductor well; and
a first drain metal covered by a bottom surface of the first second-type semiconductor region;
wherein a distance from an edge of the first first-type semiconductor well to an edge of the first high concentration second-type semiconductor region covered by the first first-type semiconductor well is a channel length.

10. The structure according to claim 6, wherein a cross section of the hexagonal active region units comprises:
a first source metal;
a first dielectric region having an upper surface covered by the first source metal;
a gate having an upper surface covered by the first dielectric region;
a second dielectric region having an upper surface covered by a bottom surface of the gate;
a first high concentration second-type semiconductor region having an upper surface contacting a bottom surface of the second dielectric region, wherein a bottom surface of the first high concentration second-type semiconductor region contacts the first first-type semiconductor well, and the first first-type semiconductor well covers the first high concentration second-type semiconductor region;
a first second-type semiconductor region covering a sidewall and a bottom surface of the first first-type semiconductor well; and
a first drain metal covered by a bottom surface of the first second-type semiconductor region;
wherein a distance from an edge of the first first-type semiconductor well to an edge of the first high concentration second-type semiconductor region covered by the first first-type semiconductor well is a channel length.

11. The structure according to claim 7, wherein a cross section of the hexagonal non-active region units comprises:
a second source metal;
a third dielectric region having an upper surface and one of the sidewalls covered by the second source metal, wherein an ending edge of the third dielectric region is a starting edge of the metal-semiconductor contact region;
a second high concentration second-type semiconductor region having one portion of an upper surface contacting a bottom surface of the third dielectric region, and the other portion of the upper surface contacting a bottom surface of the second source metal, wherein a bottom surface of the second high concentration second-type semiconductor region covers an upper surface of the second first-type semiconductor well;
a high concentration first-type semiconductor region having a bottom surface with a depth greater than the second first-type semiconductor well, wherein a portion of a sidewall of the high concentration first-type semiconductor region contacts a sidewall of the second first-type semiconductor well;
a second second-type semiconductor region covering a bottom surface of the second first-type semiconductor well and the other portion of the sidewall and a bottom surface of the high concentration first-type semiconductor region; and
a second drain metal covering a bottom surface of the second second-type semiconductor region;
wherein a range of the second source metal is the first polycrystalline gate opening region, and a range of the second source metal exclusive of the third dielectric region is the metal-semiconductor contact region.

12. The structure according to claim 11, wherein a depth of an interface of the second source metal and the high concentration first-type semiconductor region ranges between a depth of an upper surface of the second high concentration second-type semiconductor region and a depth of the second first-type semiconductor well, wherein a bottom surface of the second source metal covers an upper surface of the high concentration first-type semiconductor region, and a portion of the upper surface of the second high concentration second-type semiconductor region.

13. The structure according to claim 12, wherein a sidewall of the second source metal covers one of the sidewalls of the second high concentration second-type semiconductor region.

14. The structure according to claim 8, wherein a cross section of the hexagonal non-active region units comprises:
a second source metal connected to the first source metal;
a third dielectric region having an upper surface and a sidewall covered by the second source metal, and a sidewall respectively contacting the first dielectric region, the gate, and the second dielectric region;
a second high concentration second-type semiconductor region connected to the first high concentration second-type semiconductor region, wherein one portion of an upper surface of the second high concentration second-type semiconductor region contacts a bottom surface of the third dielectric region, and the other portion of the upper surface of the second high concentration second-type semiconductor region contacts a bottom surface of the second source metal;
a second first-type semiconductor well connected to the first first-type semiconductor well, wherein a bottom surface of the second high concentration second-type semiconductor region covers an upper surface of the second first-type semiconductor well;
a high concentration first-type semiconductor region having a portion of a sidewall contacting a portion of a sidewall of the second first-type semiconductor well;
a second second-type semiconductor region connected to the first second-type semiconductor region, wherein the second second-type semiconductor region covers a bottom surface of the second first-type semiconductor well and the other portion of the sidewall and a bottom surface of the high concentration first-type semiconductor region; and
a second drain metal connected to the first drain metal, wherein the second drain metal covers a bottom surface of the second second-type semiconductor region;
wherein a region of a combination of the second first-type semiconductor well and the high concentration first-type semiconductor region entirely covers the non-active region, a range of the second source metal is a polycrystalline gate opening region, and a range of the second source metal exclusive of the third dielectric region is a metal-semiconductor contact region.

15. The structure according to claim 1, wherein the hexagonal non-active region unit comprises:
a second polycrystalline gate opening region;
a third first-type semiconductor well;
a Schottky contact region; and
a second JFET region;
wherein the Schottky contact region and the second JFET region are hexagonal regions, the second polycrystalline gate opening region starts from an edge of the hexagonal non-active region unit, and portions in the hexagonal non-active region unit pertain to the second polycrystalline gate opening region; the third first-type semiconductor well is disposed in the second polycrystalline gate opening region, the third first-type semiconductor well is disposed between the second JFET region and the second polycrystalline gate opening region, and the third first-type semiconductor well surrounds the second JFET region; and the Schottky contact region is disposed in the second polycrystalline gate opening region, the Schottky contact region is disposed between the second JFET region and the second polycrystalline gate opening region, and a range of the Schottky contact region is smaller than the third first-type semiconductor well.

16. The structure according to claim 15, wherein a cross section of the hexagonal non-active region unit comprises:
a third source metal;
a fourth dielectric region having an upper surface and a sidewall covered by the third source metal, wherein an ending edge of the fourth dielectric region is a starting edge of the Schottky contact region;
a third high concentration second-type semiconductor region having one portion of an upper surface contacting a bottom surface of the fourth dielectric region, and the other portion of the upper surface contacting a bottom surface of the third source metal, wherein the third first-type semiconductor well covers the third high concentration second-type semiconductor region and contacts a bottom surface of the third source metal;
a third second type semiconductor region covering a bottom surface and a sidewall of the third first-type semiconductor well, wherein an interface of the third second type semiconductor region and the third source metal is a Schottky junction; and
a third drain metal covering a bottom surface of the third second type semiconductor region;
wherein a range of the third source metal is the second polycrystalline gate opening region, and a range of the second source metal exclusive of the fourth dielectric region is the Schottky contact region.

17. The structure according to claim 3, wherein the structure has the multiple hexagonal non-active region units being the three hexagonal non-active region units arranged closely adjacent to each other; wherein the high concentration first-type semiconductor regions of the three hexagonal non-active region units are arranged closely adjacent to each other, and the metal-semiconductor contact regions of the three hexagonal non-active region units are arranged closely adjacent to each other.

18. The structure according to claim 1, wherein the planar metal-oxide-semiconductor-gated semiconductor device is a metal-oxide-semiconductor field-effect transistor (MOSFET) or an insulated gate bipolar transistor (IGBT).
